(19) United States
(12) Patent Application Publication
(10) Pub. No.: US 2009/0167359 A1
(43) Pub. Date: Jul. 2, 2009

(54) CURRENT MODE LOGIC CIRCUIT AND CONTROL APPARATUS THEREFOR

(76) Inventor: Min-Hwahn Kim, Gangnam-gu (KR)

Correspondence Address: SHERR & VAUGHN, PLLC, 620 HERNDON PARKWAY, SUITE 200, HERNDON, VA, 20170, US

(21) Appl. No.: 12/344,402

(22) Filed: Dec. 26, 2008

(30) Foreign Application Priority Data
Dec. 26, 2007 (KR) 10-2007-0137003

(51) Int. Cl. H03K 19/0948; G01R 31/28

(52) U.S. Cl. 326/122; 324/763; 257/369

(57) ABSTRACT

Embodiments relate to a current mode logic circuit, which may include a first NMOS transistor whose drain may be coupled to a first load and whose gate may be coupled to an input terminal through which data may be inputted, a second NMOS transistor whose drain may be coupled to a second load and gate may be coupled to an input terminal through which a negative reference voltage may be applied, and a third NMOS transistor whose drain may be coupled to a source of each of the first and the second NMOS transistors and whose gate may be coupled to an input terminal through which a reference voltage may be applied. Bulk biases of the first, second, and third NMOS transistors may be independently adjusted to control at least one of a leakage current and an operation speed of the NMOS transistors.

The present application claims priority under 35 U.S.C. 119 to Korean Patent Application No. 10-2007-0137003 (filed on Dec. 26, 2007), which is hereby incorporated by reference in its entirety.

### BACKGROUND

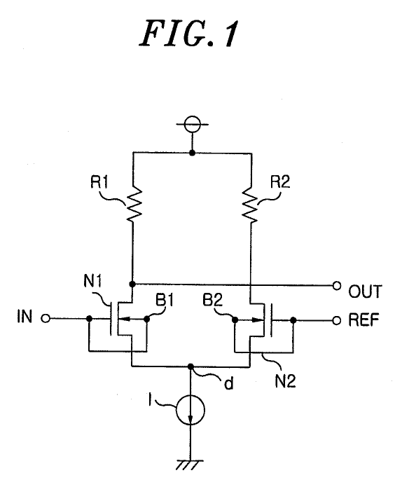

Example FIG. 1 illustrates a circuit diagram of a first example of a mode logic circuit. In example FIG. 1, reference symbols N1 and N2 may denote first and second NMOS transistors, respectively, reference symbols R1 and R2 may denote resistors, and reference symbol I may denote a constant-current source. Further, reference symbol IN may denote an input terminal connected to a gate of first NMOS transistor N1 and reference symbol OUT may denote an output terminal connected to a source of first NMOS transistor N1. Reference symbol REF may denote an input terminal of a reference voltage and reference symbol d may denote a node. Reference symbols B1 and B2 may denote body terminals of first and the second NMOS transistors N1 and N2, respectively. The first example of a mode logic circuit may be configured in a manner that body terminals B1 and B2 of first and the second NMOS transistors N1 and N2 may be coupled to their corresponding gate terminals. By such configuration, a low voltage operation may be done by lowering threshold voltages of the NMOS transistors. Moreover, a threshold voltage of first NMOS transistor N1 may be lowered because substrate bias as a voltage difference Vsb may be smaller. Therefore, in a mode logic circuit, lowering a threshold voltage of the NMOS transistor may allow a reduction of a power supply voltage. That is, a threshold voltage of an NMOS transistor may be decreased by coupling bulk bias nodes B1 and B2 of NMOS transistors N1 and N2 to IN and REF terminals, respectively, thereby enabling a low voltage operation as well as a high speed operation.

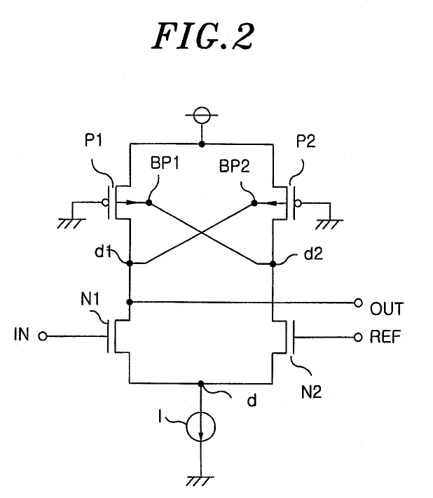

Example FIG. 2 illustrates a circuit diagram of a second example of another current mode logic circuit. In example FIG. 2, reference symbols P1 and P2 may denote first and second PMOS transistors, respectively, and reference symbols BP1 and BP2 may denote body terminals of first and second PMOS transistors P1 and P2, respectively. Reference symbols d1 and d2 may denote nodes. Further, reference symbols N1 and N2 may denote third and fourth NMOS transistors, respectively. Other elements may be the same as those of the first example described with reference to example FIG. 1.

As shown in example FIG. 2, in the second example of a mode logic circuit, resistors R1 and R2 in the current mode logic circuit of the first example may be replaced with PMOS transistors P1 and P2, respectively. In addition, body terminals BP1 and BP2 of PMOS transistors P1 and P2 may be coupled to their corresponding drains, and gates of PMOS transistors P1 and P2 may be grounded. The second example of a mode logic circuit may be configured such that body terminals BP1 and BP2 of PMOS transistors P1 and P2 may be coupled to their corresponding drains, and on-state resistance may be controlled by the control of body voltages of PMOS transistors P1 and P2. This may achieve a high speed operation. In operation, if a low level voltage is inputted to input terminal IN, NMOS transistor N1 may become in an OFF state and NMOS transistor N2 may become in an ON state. Then, a voltage at node d1 rises while a voltage at node d2 drops. Because of this, a body voltage of PMOS transistor P1 may drop and a threshold voltage of PMOS transistor P1 may drop by the effect of substrate bias. Thus, an on-state resistance of PMOS transistor P1 may drop and a voltage of output terminal OUT may rise to a power supply voltage.

On the other hand, if a high level voltage is applied to input terminal IN, NMOS transistor N1 may become in an ON state and the NMOS transistor N2 may becomes in an OFF state. Then, a body voltage at body terminal BP1 of PMOS transistor P1 may rise and thus the threshold voltage of PMOS transistor P1 may rise, so that an on-state resistance of PMOS transistor P1 may rise. This may make lower output voltage of output terminal OUT. As mentioned above, the second example of a mode logic circuit may be configured in a manner that body terminals BP1 and BP2 of PMOS transistors P1 and P2 may be coupled to their corresponding drains. By this configuration, threshold voltages of PMOS transistors P1 and P2 may rise and an output voltage of output terminal OUT may drop, thereby implementing a high speed operation. In other words, it may be designed such that bulk bias nodes BP1 and BP2 of PMOS transistors P1 and P2 as loads are cross-coupled to the output nodes d2 and d1, respectively, to control threshold voltages of PMOS transistors P1 and P2, depending on the output state, for high speed operation. In the above-described mode logic circuits, a decreased threshold voltage may enable a high speed operation, but a dynamic control of an operation speed may not be achieved because control of the threshold voltages may depend upon the input and output voltages.

### SUMMARY

Embodiments relate to a current mode logic circuit. Embodiments relate to a current mode logic circuit, which may allow a dynamic control of an operation speed, and a control apparatus therefor.

Embodiments relate to a current mode logic circuit that may control a leakage current by controlling bulk biases of transistors constituting a current mode logic circuit, and may also control the bulk biases when a high speed operation, rather than the leakage current, is required in its applications, to thereby achieve such high speed operation.

According to embodiments, a current mode logic circuit may include at least one of the following. A first NMOS transistor whose drain may be coupled to a first load and gate may be coupled to an input terminal through which data may be inputted. A second NMOS transistor whose drain may be coupled to a second load and gate may be coupled to an input terminal through which a negative reference voltage may be applied. A third NMOS transistor whose drain may be coupled to a source of each of the first and second NMOS transistors and gate may be coupled to an input terminal through which a reference voltage may be applied. According to embodiments, bulk biases of the first, the second and the third NMOS transistors may be adjusted to control a leakage current and/or an operation speed of the NMOS transistors.

According to embodiments, a control apparatus for a current mode logic circuit having a plurality of transistors and controlling bulk biases of the transistors to control a leakage current and/or an operation speed of the transistors may include at least one of the following. A current mode logic unit including a test circuit which may initialize bulk biases of the transistors and may detect a test output signal of the current mode logic circuit. A power management unit that may apply the bulk biases to the transistors in response to a voltage control signal. A controller that may compare the test output signal received from the test circuit with a predetermined performance reference value and, based thereon, may provide the voltage control signal to the power management unit until the comparison result reaches a desired performance.

According to embodiments, bulk biases of transistors constituting a current mode logic circuit may be adjusted to control a leakage current and to enable a dynamic control of an operation speed when a high speed operation, rather than the leakage current, is required in its applications.

### DRAWINGS

Example FIG. 1 illustrates a circuit diagram of a first example of a current mode logic circuit.

Example FIG. 2 illustrates a circuit diagram of a second example of a current mode logic circuit.

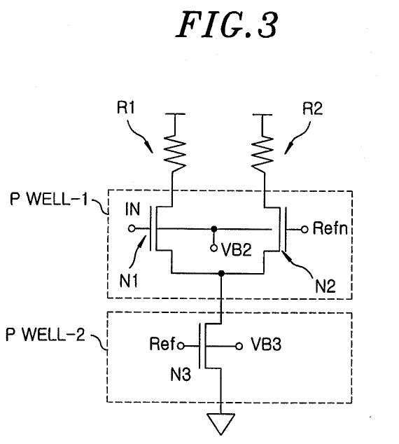

Example FIG. 3 illustrates a circuit diagram of a current mode logic circuit according to embodiments.

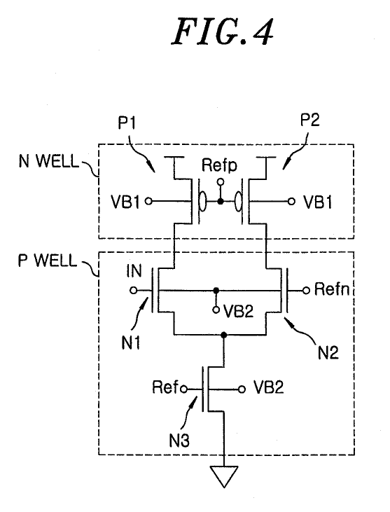

Example FIG. 4 illustrates a circuit diagram of a current mode logic circuit according to embodiments.

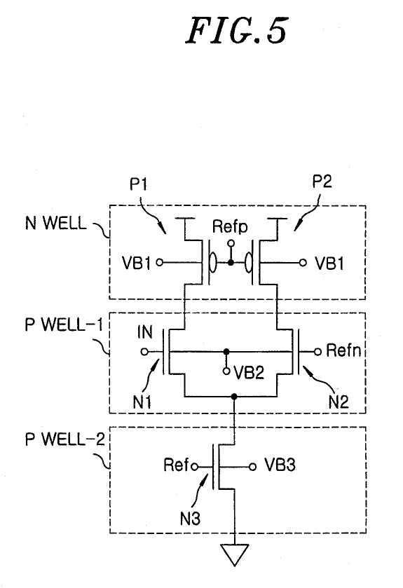

Example FIG. 5 illustrates a circuit diagram of a current mode logic circuit according to embodiments.

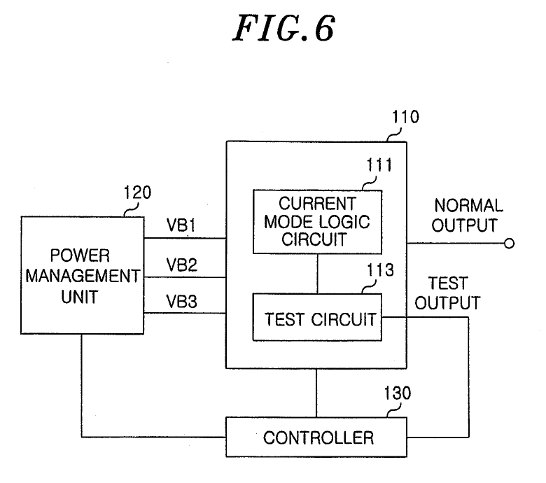

Example FIG. 6 illustrates a block diagram of a control apparatus for a current mode logic circuit according to embodiments.

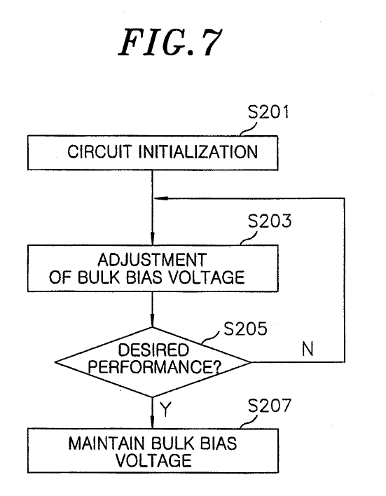

Example FIG. 7 illustrates a flowchart for describing an operational procedure of a control apparatus for a current mode logic circuit according to embodiments.

### DESCRIPTION

Example FIG. 3 illustrates a circuit diagram of a current mode logic circuit according to embodiments. Referring to example FIG. 3, reference symbols N1, N2 and N3 may denote first, second and third NMOS transistors, respectively. Reference symbols R1 and R2 may denote first and second resistors. Reference symbol IN may denote an input terminal coupled to a gate of first NMOS transistor N1. Reference symbol Ref may denote a reference voltage input terminal of third NMOS transistor N3. Reference symbol Refn may denote a reference voltage input terminal of second NMOS transistor N2. Reference symbol VB2 may denote a bulk bias of P well-1, and reference symbol VB3 may denote a bulk bias of P well-2. According to embodiments, resistors R1 and R2 may be loads and third NMOS transistor N3 may be a current source.

According to embodiments, a device may be configured to include first NMOS transistor N1 whose drain may be coupled to first load resistor R1 and gate may be coupled to input terminal IN through which data may be inputted. Drain of second NMOS transistor N2 may be coupled to second load resistor R2 and its gate may be coupled to input terminal Refn through which a negative reference voltage may be inputted. Drain of third NMOS transistor N3 may be coupled to a source of each of first and second NMOS transistors N1 and N2 and its gate may be coupled to input terminal Ref through which a reference voltage may be inputted. In this configuration, bulk bias VB2 may be applied to a body terminal of first and second NMOS transistors N1 and N2 and bulk bias VB3 may be applied to a body terminal of third NMOS transistor N3.

According to embodiments, P well-1 and P well-2 control, respectively and independently, bulk bias VB2 of first and second NMOS transistors N1 and N2 and bulk bias VB3 of third NMOS transistor N3. According to embodiments, it may be designed such that a desired speed operation may be done by controlling a threshold voltage of each of NMOS transistors N1, N2 and N3 by independent control of each of P well-1 and P well-2. According to embodiments, a threshold voltage of each of NMOS transistors N1, N2 and N3 may be controlled to be dropped or raised by the control of the bulk bias voltages. This may control an operation speed of the circuit.

Example FIG. 4 illustrates a circuit diagram of a current mode logic circuit according to embodiments. In example FIG. 4, reference symbols N1, N2 and N3 may denote first, second and third NMOS transistors, respectively. Reference symbols P1 and P2 may denote first and second PMOS transistors, respectively. Reference symbol IN may denote an input terminal coupled to a gate of first NMOS transistor N1. Reference symbol Ref may denote an input terminal of a reference voltage. Reference symbol Refn may denote a reference voltage input terminal of second NMOS transistor N2. Reference symbol Refp may denote a reference voltage input terminal of first and second PMOS transistors P1 and P2. Reference symbol VB1 may denote a bulk bias of an N well, and reference symbol VB2 may denote a bulk bias of a P well.

According to embodiments, a device may include transistors P1 and P2 whose gates may be coupled to input terminal Refp through which a positive reference voltage may be applied. A drain of first NMOS transistor N1 may be coupled to a source of first PMOS transistor P1 and its gate may be coupled to input terminal IN through which data may be inputted. A drain of second NMOS transistor N2 may be coupled to a source of second PMOS transistor P2 and gate may be coupled to input terminal Refn through which a negative reference voltage may be applied. A drain of third NMOS transistor N3 may be coupled to a source of each of first and second NMOS transistors N1 and N2 and its gate may be coupled to an input terminal Ref through which a reference voltage may be applied. According to embodiments, bulk bias VB1 may be applied to body terminals of transistors P1 and P2, and bulk bias VB2 may be inputted to body terminals of first, second, and third NMOS transistors N1, N2 and N3.

According to embodiments, load resistors R1 and R2 (FIG. 3.) in the current mode logic circuit of embodiments set forth above may be replaced with PMOS transistors P1 and P2, respectively. Further, bulk bias VB1 of the load PMOS transistors P1 and P2, which may be arranged in the N well, may be added to control the load resistance independently.

According to embodiments, N well may control a voltage of bulk bias VB1 of first and second PMOS transistors P1 and P2, while the P well may control the voltage of bulk bias VB2 of first, second, and third NMOS transistors N1, N2 and N3 independently. According to embodiments, independent control of each of the N well and the P well may allow control of a threshold voltage of each of PMOS transistors P1 and P2 and NMOS transistors N1, N2 and N3, which may achieve a high speed operation.

Example FIG. 5 illustrates a circuit diagram of a current mode logic circuit according to embodiments. In example FIG. 5, reference symbols N1, N2 and N3 may denote first, second and third NMOS transistors, respectively. Reference symbols P1 and P2 may denote first and second PMOS transistors, respectively. Further, reference symbol IN may denote an input terminal coupled to a gate of first NMOS transistor N1. Reference symbol Ref may denote a reference voltage input terminal of third NMOS transistor N3. Reference symbol Refn may denote a reference voltage input terminal of second NMOS transistor N2. Reference symbol Refp may denote a reference voltage input terminal of transistors P1 and P2. Reference symbol VB1 may denote a bulk bias of N well. Reference symbol VB2 may denote a bulk bias of P well-1, and reference symbol VB3 may denote a bulk bias of P well-2.

According to embodiments, a device may include transistors P1 and P2 whose gates may be coupled to input terminal Refp through which a positive reference voltage may be applied. It may further include first NMOS transistor N1 whose drain may be coupled to a source of first PMOS transistor P1 and whose gate may be coupled to input terminal IN through which data may be inputted.

It may also include second NMOS transistor N2 whose drain may be coupled to a source of second PMOS transistor P2 and whose gate may be coupled to input terminal Refn through which a negative reference voltage may be applied. It may further include third NMOS transistor N3 whose drain may be coupled to a source of each of first and second NMOS transistors N1 and N2 and whose gate may be coupled to the input terminal Ref through which a reference voltage may be applied.

According to embodiments, bulk bias VB1 may be applied to body terminals of first and second PMOS transistors P1 and P2. Bulk bias VB2 may be inputted to body terminals of first and second NMOS transistors N1 and N2. Bulk bias VB3 may be applied to a body terminal of third NMOS transistor N3. In a current mode logic circuit according to embodiments, the P well in the current mode logic circuit of embodiments described above may be divided into P well-1 and P well-2.

According to embodiments, the N well may control a voltage of bulk bias VB1 of PMOS transistors P1 and P2. P well-1 may control a voltage of bulk bias VB2 of NMOS transistors N1 and N2. P well-2 may control a voltage of bulk bias VB3 of the NMOS transistor N3. That is to say, independent control of each of the N well, P well-1 and P well-2 may allow for control of a threshold voltage of each of PMOS transistors P1 and P2 and NMOS transistors N1, N2 and N3. This may achieve a high speed operation.

Example FIG. 6 illustrates a block diagram illustrating a configuration of a control apparatus for a current mode logic circuit according to embodiments. Referring to example FIG. 6, a control apparatus for a current mode logic circuit may include current mode logic unit 110, which may have current mode logic circuit 111 and test circuit 113, which may initialize a bulk bias of current mode logic circuit 111. It may also include power management unit 120, which may apply a bulk bias to current mode logic circuit 111 in response to a voltage control signal. It may also include controller 130, which may compare a test output signal of current mode logic circuit 11 detected by test circuit 113 with a predetermined performance reference value and, based thereon, may provide a voltage control signal to power management unit 130 until the comparison result reaches a desired performance.

Example FIG. 7 illustrates a flowchart describing an operational procedure of a control apparatus for a current mode logic circuit according to embodiments. A control procedure of a current mode logic circuit will be described with reference to example FIGS. 6 and 7.

According to embodiments, if the current mode logic circuit control apparatus enters a test mode, test circuit 113 may initialize bulk biases VB1, VB2 and VB3 of the NMOS transistors and the PMOS transistors of current mode logic circuit 111 in response to a control signal from controller 130 (step S201). Alternatively, test circuit 113 may perform an initialization of the bulk biases when its operation starts, regardless of a control signal from controller 130.

Next, controller 130 may compare a test output signal of current mode logic circuit 111 detected by test circuit 113 with a predetermined performance reference value, and based thereon may provide a voltage control signal to power management unit 120 until the comparison result reaches a desired performance. According to embodiments, since the bulk bias of current mode logic circuit 111 may be initialized at an initial operation, controller 130 may provide power management unit 120 with a voltage control signal for application of bulk biases.

According to embodiments, power management unit 120 may apply the bulk biases through body terminals of the NMOS transistors and the PMOS transistors of current mode logic circuit 111 in response to the voltage control signal from controller 130. Then, test circuit 113 may detect a test output signal of current mode logic circuit 111 and may provide it to controller 130.

Controller 130 may compare a test output signal of current mode logic circuit 111 detected by test circuit 113 with a predetermined performance reference value, and based thereon may provide a voltage control signal to power management unit 120 until the comparison result reaches a desired performance. Accordingly, a bulk bias voltage applied to current mode logic circuit 111 may be adjusted (steps S203 and S205). According to embodiments, controller 130 may control a threshold voltage of each of the transistors constituting current mode logic circuit 111 by adjusting a bulk bias voltage to lower or raise a threshold voltage, and may thereby control an operation speed of the circuit. According to embodiments, steps S203 and S205 may be repetitively performed until current mode logic circuit 111 reaches a desired performance, i.e., desired timing and power.

When output characteristics of current mode logic circuit 111 reach a desired performance, controller 130 may send a control signal to power management unit 120 to maintain a bulk bias being currently applied to current mode logic circuit 111 so that current mode logic circuit 111 may enter a normal mode and may provide a normal output (step S207).

According to embodiments, when an operation of current mode logic circuit 111 is not needed, controller 130 may maximize a threshold voltage of each of the transistors constituting current mode logic circuit 111 through use of power management unit 120. This may minimize the leakage current.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A device comprising:
a first NMOS transistor having a drain coupled to a first load and a gate coupled to an input terminal configured to receive input data;
a second NMOS transistor having a drain coupled to a second load and a gate coupled to an input terminal through which a negative reference voltage is applied; and
a third NMOS transistor having a drain coupled to a source of each of the first and the second NMOS transistors and a gate coupled to an input terminal through which a reference voltage is applied,
wherein bulk biases of the first, second, and third NMOS transistors are adjusted to control at least one of a leakage current and an operation speed of the NMOS transistors.

2. The device of claim 1, wherein the drain of the first NMOS transistor is coupled to a first load resistor as the first load and the drain of the second NMOS transistor is coupled to a second load resistor as the second load.

3. The device of claim 1, wherein a first bulk bias is provided to the first and second NMOS transistors, and wherein a second bulk bias is provided to the third NMOS transistor.

4. The device of claim 3, wherein the first bulk bias and second bulk bias are adjusted independently.

5. The device of claim 4, wherein the third NMOS transistor comprises a current source.

6. The device of claim 4, wherein the first and the second NMOS transistors comprise a first P well and the third NMOS transistor comprises a second P well.

7. The device of claim 1, further comprising a first PMOS transistor and a second PMOS transistor, wherein the drain of the first NMOS transistor is coupled to a source of the first PMOS resistor as the first load, the drain of the second NMOS transistor is coupled to a source of the second PMOS transistor as the second load, and a gate of each of the first and the second PMOS transistors is coupled to an input terminal configured to provide a positive reference voltage.

8. The device of claim 7, wherein a first bulk bias is provided to the first and second PMOS transistors, and wherein a second bulk bias is provided to the first, second, and third NMOS transistors.

9. The device of claim 8, wherein the first bulk bias and the second bulk bias are adjusted independently.

10. The device of claim 9, wherein the first and second PMOS transistors comprise an N well, and the first, second, and third NMOS transistors comprise a P well.

11. The device of claim 1, further comprising a first PMOS transistor and a second PMOS transistor, wherein the drain of the first NMOS transistor is coupled to a source of the first PMOS resistor as the first load, the drain of the second NMOS transistor is coupled to a source of the second PMOS transistor as the second load, and a gate of each of first and the second PMOS transistors is coupled to an input terminal through which a positive reference voltage is applied, wherein a first bulk bias is provided to the first and second PMOS transistors, a second bulk bias is provided to the first and second NMOS transistors, and a third bulk bias is provided to the third NMOS transistor.

12. The device of claim 11, wherein the first, second, and third bulk biases are adjusted independently.

13. The device of claim 12, wherein the first and second PMOS transistors comprise an N well, the first and second NMOS transistors comprise a first P well, and the third NMOS transistor comprises a second P well.

14. A device comprising:
a current mode logic unit including a test circuit and a current mode logic circuit, the test circuit configured to initialize at least two bulk biases to be provided to designated ones of a plurality of transistors, and to detect a test output signal of the current mode logic circuit;
a power management unit configured to apply the at least two bulk biases to the designated ones of the plurality of transistors in response to a voltage control signal; and
a controller configured to compare the test output signal received from the test circuit with a predetermined performance reference value and provide the voltage control signal to the power management unit until a result of the comparison achieves prescribed performance criteria.

15. The device of claim 14, wherein the controller controls the at least two bulk biases through the power management unit to maximize a threshold value of each of the plurality of transistors to minimize a leakage current, when operation of the current mode logic circuit is not required.

16. The device of claim 14, wherein the prescribed performance criteria comprises at least one of desired timing and desired power.

17. The device of claim 14, wherein, when the result of the comparison reaches the prescribed performance criteria, the controller sends the voltage control signal to the power management unit to maintain a value of each of at least two bulk biases currently being applied to the current mode logic circuit and the current mode logic circuit enters a normal mode.

18. The device of claim 14, wherein the at least two bulk biases comprise a first bulk bias and a second bulk bias, the first and second bulk biases being independently controlled.

19. The device of claim 18, wherein the first bulk bias is provided to a P well of the current mode logic circuit and the second bulk bias is provided to an N well of the current mode logic circuit.

20. The device of claim 18, wherein the at least two bulk biases comprises a third bulk bias, which is controlled independently of the first and second bulk biases.
